(19) United States
(12) Patent Application Publication
(10) Pub. No.: US 2006/0208265 A1
(43) Pub. Date: Sep. 21, 2006

(54) Light emitting diode and light emitting diode array

(75) Inventors: Tomihisa Yukimoto, Hitachi (JP); Eiichi Kunitake, Hitachi (JP); Yukio Sasaki, Takahagi (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Hitachi Cable, Ltd., Tokyo (JP)

(21) Appl. No.: 11/272,761

(22) Filed: Nov. 15, 2005

(30) Foreign Application Priority Data
Mar. 17, 2005 (JP) 2005-076750
Jun. 30, 2005 (JP) 2005-191375

(51) Int. Cl. H01L 33/00

(52) U.S. Cl. 257/88

(57) ABSTRACT

A light emitting diode array comprises compound semiconductor layers epitaxially grown on a p-type GaAs conductive layer 11 formed on a semi-insulating GaAs substrate 30. The epitaxial layer is isolated and divided into a plurality of light emitting parts 1 which function as a light emitting diode. A Si-doped n-type GaAs buffer layer 31 is interposed between the semi-insulating GaAs substrate 30 and the p-type GaAs conductive layer 11. In the light emitting diode array comprising this epitaxial configuration, it is possible to prevent the short-circuit defect due to diffusion of p-type dopant from the p-type GaAs conductive layer into the semi-insulating GaAs substrate made by the LEC method.

The present application is based on Japanese Patent Application Numbers 2005-76750 (filed on Mar. 17, 2005) and 2005-191375 (filed on Jun. 30, 2005), the entire contents of which are incorporated herein by reference.

### BACKGROUND OF THE INVENTION

1. Field of the Invention

This invention relates to a light emitting diode and a light emitting diode array using a semi-insulating GaAs substrate with general versatility which is fabricated by a LEC (Liquid Encapsulated Czochralski) method, and more particularly, to a light emitting diode and a light emitting diode array having a high emission power which can be preferably used for a light source of an electronographic type printer.

2. Description of the Related Art

In the electronographic type printer, an electrostatic latent image is formed on a photoconductive drum by a light corresponding to an image signal then the electrostatic latent image is copied into a paper to obtain a printed image. As a light source for forming a latent image, a laser type light source and a light emitting diode array type light source are broadly used. In particular, the light emitting diode array type light source is suitable for a small sized printer or a printer for printing a large size image, since it is not necessary to provide a long optical path length like the laser type printer.

In recent years, a light emitting diode array with high precision, high output power, and low cost has been required in accordance with the needs of high speed and high image quality and a further miniaturization of the printer.

Japanese Patent Laid-Open No. 6-302856 (JP-A-6-302856) discloses a conventional light emitting diode array using a n-type GaAs substrate. A light emitting part of this light emitting diode array has a so-called double heterostructure, which comprises a n-type GaAs substrate, a n-type GaAs buffer layer, a n-type AlGaAs cladding layer, an AlGaAs active layer, a p-type AlGaAs cladding layer, and p-type AlGaAs current diffusion layer, first and second p-type GaAs cap layers, sequentially grown on the n-type GaAs substrate. Further, a p-type electrode is provided on a mesa top surface of the p-type GaAs cap layer, and a n-type electrode is provided under the n-type GaAs substrate.

However, so as to realize a reduction in fabrication cost of the light emitting diode array, it is profitable to use a semi-insulating GaAs substrate with general versatility which is made by the LEC method, rather than a n-type GaAs substrate made by a VGF (Vertical Gradient Freeze) method.

Herein, the VGF method is a method for fabricating a single crystal, comprising steps of putting a seed crystal in a lower part of a crucible made of pyrolytic boron nitride (PBN) grown by the high temperature vapor phase epitaxy, providing a GaAs polycrystal above the seed crystal, accommodating the crucible in a vertical type electric furnace having an upper part with a high temperature and a lower part with a low temperature, and growing a single crystal from the seed crystal towards an upper direction. Japanese Patent Laid-Open No. 5-70276 (JP-A-5-70276) discloses an example of the VGF method. On the other hand, the LEC method is a method for fabricating a single crystal such as a GaAs single crystal, comprising steps of putting a GaAs base material melt and a liquid encapsulation agent in a crucible made of PBN, making a seed crystal contact with the GaAs base material melt, and raising the seed crystal slowly while turning the seed crystal relatively to the crucible. Japanese Patent Laid-Open No. 5-24979 (JP-A-5-24979) discloses an example of the LEC method.

In addition, although a semi-insulating GaAs substrate is not used but a silicon substrate is used, it has bee known a semiconductor light emitting device structure, in which a double heterostructure for a light emitting part is provided on one surface of the silicon substrate via a buffer layer and an ohmic contact layer interposed on the silicon substrate. Japanese Patent Laid-Open No. 6-232454 (JP-A-6-232454) discloses an example of the above-described light emitting device structure in paragraph 0013. In JP-A-6-232454, it is explained that this buffer layer is mainly composed of GaAsP, GaP, etc., and a strained superlattice layer is existed in the middle of growth layers. JP-A-6-232454 discloses that, for instance, the buffer layer is mainly composed of a GaAs crystal and the strained superlattice layer is composed of InGaAs and GaAs.

However, the silicon substrate is used and the semi-insulating GaAs substrate is not used in the JP-A-6-232454.

The use of a semi-insulating GaAs substrate in a light emitting diode array means that the use of a GaAs crystal with general versatility which is made by the LEC method. Therefore, it is very advantageous for realizing the reduction in fabrication cost of the light emitting diode array.

However, even if a semi-insulating GaAs substrate made by the LEC method is used in the conventional light emitting part structure, instead of a n-type GaAs substrate made by the VGF method, following problems will be occurred.

For example, the light emission part of a conventional light emitting diode has a structure in which a p-type GaAs conductive layer is directly provided on a GaAs substrate. After sequentially growing a p-type AlGaAs etching stopper layer, a p-type AlGaAs cladding layer, a p-type AlGaAs active layer, a n-type AlGaAs cladding layer, and a n-type GaAs cap layer on the p-type GaAs conductive layer, a device manufacturing process (to expose the grown layers to a high temperature of 400° C at maximum) is conducted to complete the light emitting part. When this device manufacturing process is conducted for the conventional light emitting diode array, Zn which is used as a p-type dopant for the p-type GaAs conductive layer may be diffused into the semi-insulating GaAs substrate, and the diffused Zn cannot be completely isolated and separated by a device isolation trench, thereby causing a short-circuit between respective light emitting parts. As a result, there occurs a defect in that undesired light emitting parts of the light emitting diode (LED) also emit the light.

### SUMMARY OF THE INVENTION

Accordingly, it is an object of the invention to provide an epitaxial configuration for a light emitting diode array, which can prevent a short-circuit due to diffusion of p-type dopant from a p-type GaAs conductive layer into a semi-insulating GaAs substrate, even if the semi-insulating GaAs substrate made by the LEC method is used in a light emitting diode array, so as to solve the above problems.

According to a first feature of the invention, a light emitting diode, comprises:

a semi-insulating GaAs substrate;

a GaAs system conductive layer doped with p-dopants which is provided on the semi-insulating GaAs substrate;

a GaAs system light emitting portion provided on the GaAs system conductive layer;

a n-electrode provided on the GaAs system light emitting portion;

a p-electrode provided on a side of the GaAs system light emitting portion and on the semi-insulating GaAs substrate, the p-electrode being connected to the GaAs system conductive layer; and

a GaAs system layer provided between the semi-insulating GaAs substrate and the GaAs system conductive layer, the GaAs system layer preventing the p-dopants from diffusing into the semi-insulating GaAs substrate.

According to a second feature of the invention, in the light emitting diode, the GaAs system layer is a n-GaAs buffer layer doped with Si.

According to a third feature of the invention, in the light emitting diode, the GaAs system layer is a superlattice layer including AlGaAs and GaAs layers doped with Si.

According to a fourth feature of the invention, a light emitting diode array, comprises:

a plurality of light emitting diodes being isolated and separated comprising:

a semi-insulating GaAs substrate;

a p-type GaAs conductive layer provided on the semi-insulating GaAs substrate; and

compound semiconductor layers epitaxially grown on the p-type GaAs conductive layer to provide the plurality of light emitting diodes;

wherein:

a Si-doped n-type GaAs buffer layer is interposed between the semi-insulating GaAs substrate and the p-type GaAs conductive layer.

According to this feature, since a Si-doped n-type GaAs buffer layer is provided in the middle of grown layers, it is possible to prevent Zn, which is used as a p-type dopant for a p-type GaAs conductive layer, being diffused into a semi-insulating GaAs substrate, that may cause a short-circuit defect between respective light emitting parts.

According to a fifth feature of the invention, a Si-doped GaAs/AlGaAs superlattice buffer layer may be interposed under the Si-doped n-type GaAs buffer layer provide between the semi-insulating GaAs substrate and the p-type GaAs conductive layer.

According to a sixth feature of the invention, the light emitting diode array, further comprises:

a mesa etching groove for defining the plurality of light emitting diodes, which has an enough depth to divide the p-type GaAs conductive layer and to reach the Si-doped n-type GaAs buffer layer.

According to seventh feature, it is possible to realize the object of the mesa etching groove to isolate and separate grown layers into a plurality of light emitting parts of the LED sufficiently.

According to an eighth feature of the invention, the light emitting diode array further comprises:

a mesa etching groove for defining the plurality of light emitting parts, having an enough depth to divide the p-type GaAs conductive layer and to reach the Si-doped n-type GaAs buffer layer.

According to the present invention, since a Si-doped n-type GaAs buffer layer is interposed between the semi-insulating GaAs substrate and the p-type GaAs conductive layer in the light emitting diode array, it is possible to prevent a short-circuit defect caused by diffusion of Zn used as a dopant for the p-type GaAs conductive layer into the semi-insulating GaAs substrate.

Accordingly, without using an expensive n-type GaAs substrate made by the VGF method, it is possible to apply an inexpensive GaAs substrate with the general versatility, which is made by LEC method.

According to this structure, Zn used as a dopant for the p-type GaAs conductive layer is diffused into the buffer layer during crystalline growth or heat treatment in the device fabrication process. However, by interposing a Si-doped n-type GaAs buffer layer, a concentration of Zn in the conductive layer is offset by a concentration of Si used as a dopant of the Si-doped n-type GaAs buffer layer, so that the effect of the present invention can be obtained.

### BRIEF DESCRIPTION OF THE DRAWINGS

Preferred embodiments of the invention will be described in conjunction with appended drawings, wherein:

FIG.1 is a plan view showing an enlarged part of a configurative example of a light emitting diode array;

FIGS.2A and 2B are cross sectional views showing the light emitting diode array shown in FIG.1, wherein FIG.2A is a cross sectional view of FIG. 1 cut along A-A′ line, and FIG. 2B is a cross sectional view of FIG. 1 cut along B-B′ line;

FIG. 3 is an enlarged cross sectional view of a light emitting part of the light emitting diode array shown in FIG. 2B;

FIG. 4 is a plan view showing an enlarged part of a light emitting diode array in a first preferred embodiment according to the invention;

FIGS. 5A and 5B are cross sectional views showing the light emitting diode array in the first preferred embodiment shown in FIG. 4, wherein FIG. 5A is a cross sectional view of FIG. 4 cut along A-A′ line, and FIG. 5B is a cross sectional view of FIG. 4 cut along B-B′ line;

FIG. 6 is an enlarged cross sectional view of a light emitting part of the light emitting diode array shown in FIG. 5B; and

FIG. 7 is a cross sectional view showing an epitaxial configuration of a light emitting part of a light emitting diode array in a second preferred embodiment of the present invention.

### DETAILED DESCRIPTION OF THE PREFERRED EMBODIMENTS

Next, a light emitting diode array in a preferred embodiment according to the present invention will be explained.

(Configuration of a Light Emitting Diode Array)

For the purpose of explaining the present invention, a configuration of a light emitting diode array will be explained first.

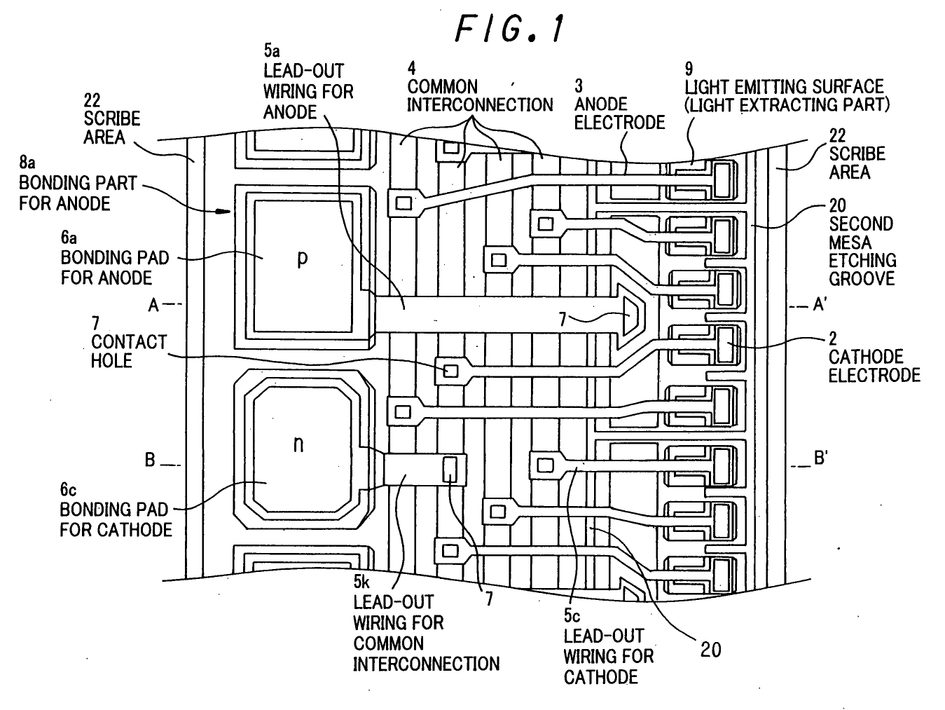

FIG. 1 is a plan view showing an enlarged part of a configurative example of a four-divided matrix light emitting diode array.

According to a design configuration of this four-divided matrix light emitting diode array, light emitting parts are disposed in a line. A bonding pad 6c for cathode, which is connected with a cathode electrode 2 via common interconnections 4 and a bonding pad 6a for anode are disposed in an array.

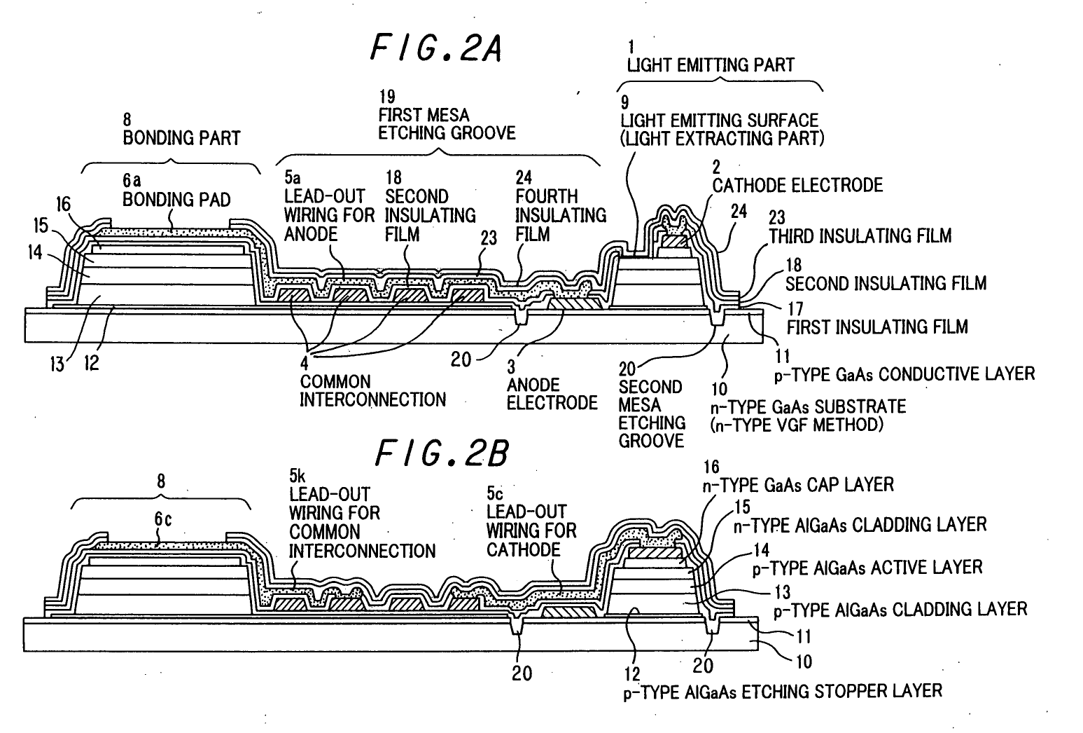

FIGS. 2A and 2B are cross sectional views showing a representative part of the four-divided matrix light emitting diode array shown in FIG. 1, wherein FIG. 2A is a cross sectional view of FIG. 1 cut along A-A′ line, and FIG. 2B is a cross sectional view of FIG. 1 cut along B-B′ line. This light emitting diode array comprises a n-type GaAs substrate 10 made by the VGF method, a plurality of light emitting parts 1 formed on the n-type GaAs substrate 10, a cathode electrode 2 having a convex shape which is partially formed on a top surface of each of light emitting part 1, and an anode electrode 3 formed on a p-type GaAs conductive layer 11. A light emitting surface (light extracting part) 9 is sandwiched between the cathode electrode 2 and the anode electrode 3.

According to this example shown in FIGS. 1, 2A and 2B, in each light emitting part 1, an epitaxial layer uniformly grown on the n-type GaAs substrate 10 is provided with mesa etching grooves, so that the epitaxial layer isolated and separated by mesa etching grooves is sectioned into respective independent epitaxial layer parts.

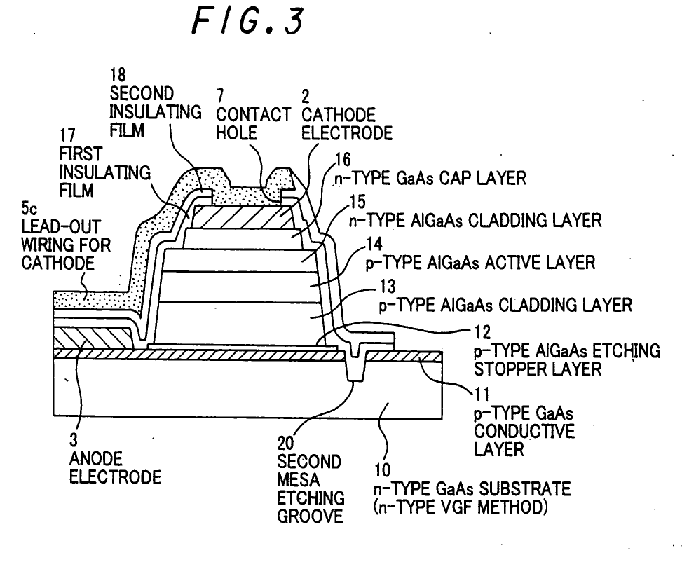

FIG. 3 is an enlarged cross sectional view of a light emitting part 1 of a light emitting diode array shown in FIG. 2B.

The light emitting part 1 of this light emitting diode array has a so-called double heterostructure, which comprises the n-type GaAs substrate 10, a p-type AlGaAs etching stopper layer 12, a p-type AlGaAs cladding layer 13, a p-type AlGaAs active layer 14, a n-type AlGaAs cladding layer 15, and a n-type GaAs cap layer 16, sequentially grown on the a p-type GaAs conductive layer 11 which is provided on the n-type GaAs substrate 10. Further, the cathode electrode 2 is provided on a mesa top surface of the n-type GaAs cap layer 16, and the anode electrode 3 is provided on the p-type GaAs conductive layer 11.

One may assume a semi-insulating GaAs substrate made by the LEC method is used instead of a n-type GaAs substrate made by the VGF method in the light emitting part structure shown in FIG. 3, in which a p-type GaAs conductive layer 11 is directly provided on a GaAs substrate. After sequentially growing a p-type AlGaAs etching stopper layer 12, a p-type AlGaAs cladding layer 13, a p-type AlGaAs active layer 14, a n-type AlGaAs cladding layer 15, and a n-type GaAs cap layer 16 on the p-type GaAs conductive layer 11, a device manufacturing process (to expose the grown layers to a high temperature, maximum 400° C.) is conducted to complete the light emitting part 1. When this device manufacturing process is conducted, Zn which is used as a p-type dopant for the p-type GaAs conductive layer 11 may be diffused into the semi-insulating GaAs substrate, and the diffused Zn cannot be completely isolated by a device isolation trench (a second mesa etching groove 20), thereby causing a short-circuit between respective light emitting parts 1. As a result, there occurs a defect in that undesired light emitting parts 1 also emits the light.

The present invention is different in a substrate and a part of the epitaxial configuration from this example of the light emitting diode array shown in FIGS. 1 to 3.

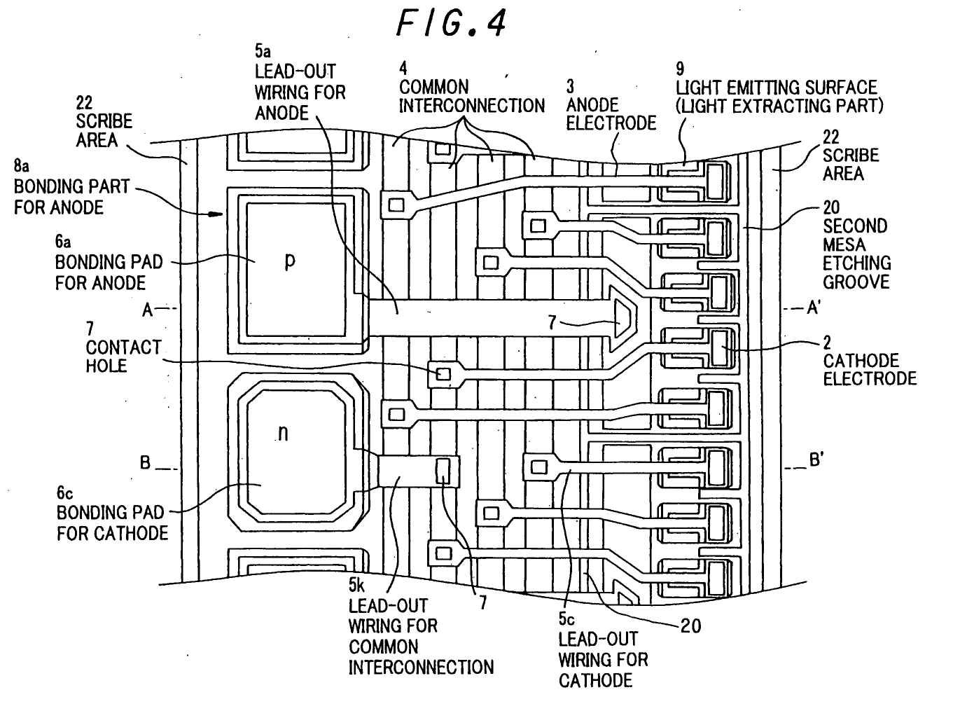

FIG. 4 is a plan view showing a light emitting diode array in a first preferred embodiment according to the invention.

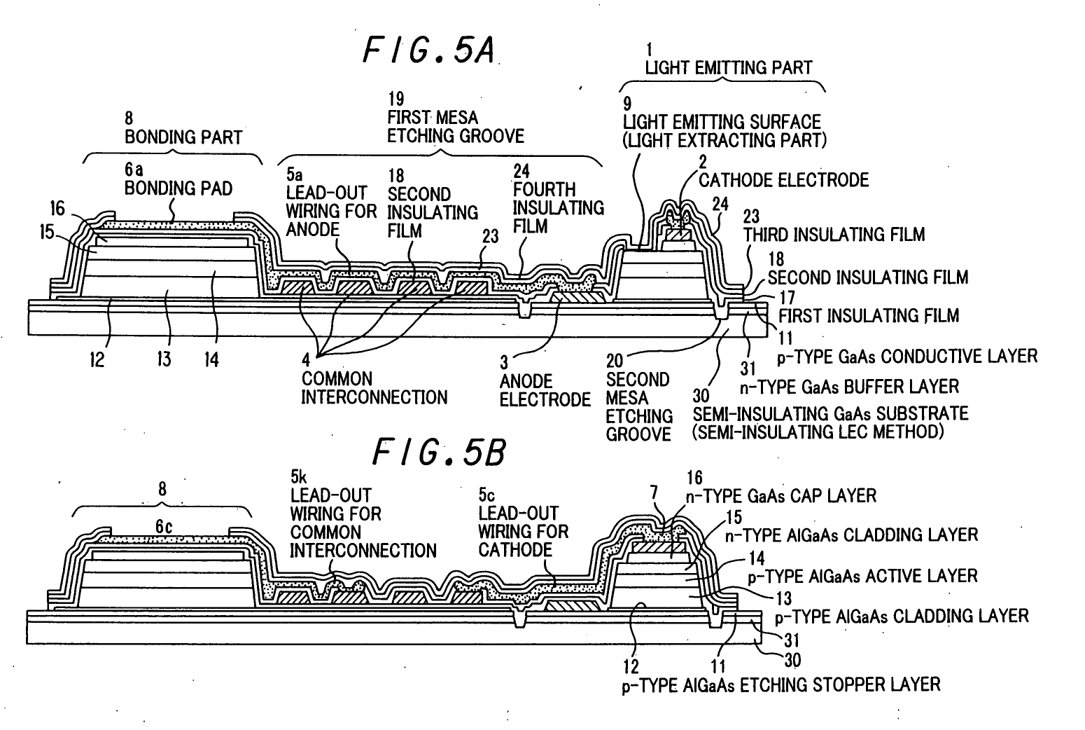

FIGS. 5A and 5B are cross sectional views showing a representative part of a four-divided matrix light emitting diode array shown in FIG. 4, wherein FIG. 5A is a cross sectional view of FIG. 4 cut along A-A′ line, and FIG. 5B is a cross sectional view of FIG. 4 cut along B-B′ line.

The present invention is different from the example of the four-divided matrix light emitting diode array shown in FIGS. 2A and 2B, in which a semi-insulating GaAs substrate 30 made by the LEC method is used as a substrate, and a Si-doped n-type GaAs buffer layer 31 is interposed directly on the semi-insulating GaAs substrate 30. Other elements are similar to those in the example of the four-divided matrix light emitting diode array shown in FIGS. 2A and 2B.

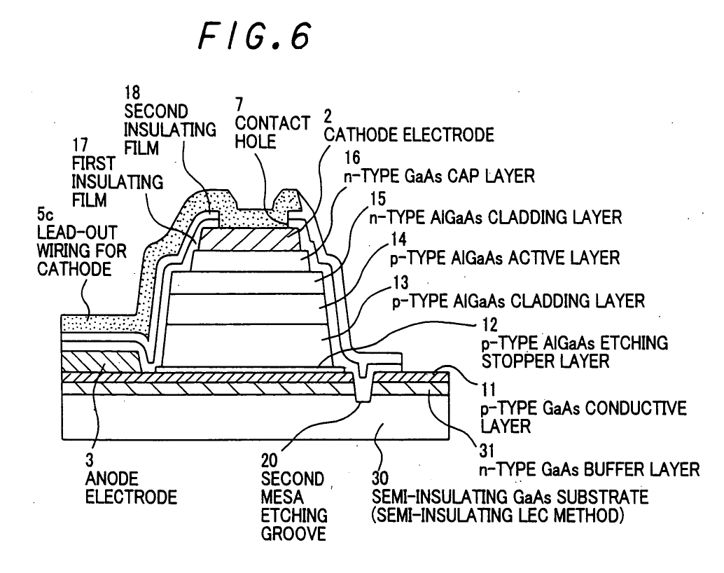

FIG. 6 is an enlarged cross sectional view of a light emitting part 1 of the light emitting diode array shown in FIG. 5B.

A comparison between the structure of the substrate and epitaxial layer of the light emitting diode array in the example and in the present invention will be understood referring to FIGS. 3 and 6.

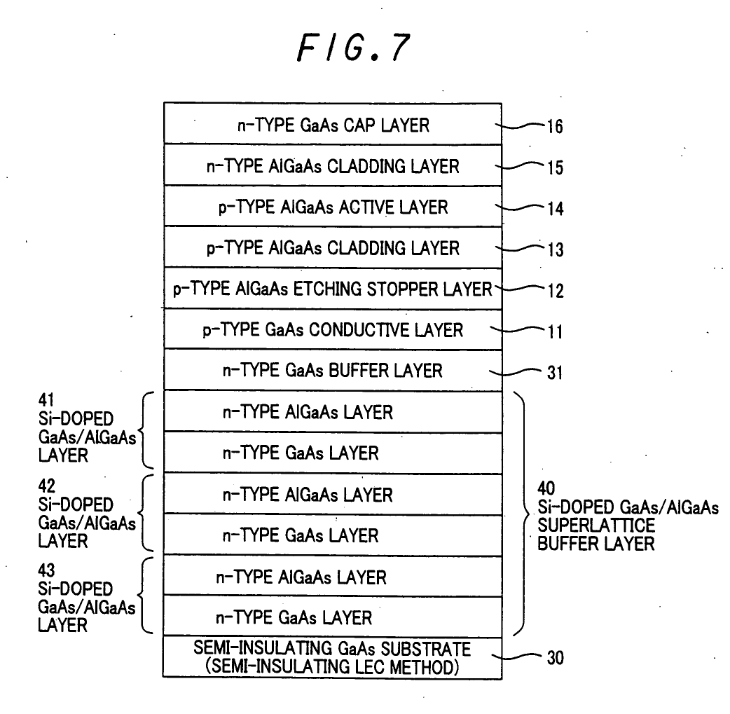

FIG. 7 is a cross sectional view showing a layered structure of a light emitting part 1 of a light emitting diode array in a second preferred embodiment of the present invention. The second preferred embodiment is a variation of the first preferred embodiment, for instance, a Si-doped GaAs/AlGaAs superlattice buffer layer 40 comprising three layers 41 to 43 of Si-doped AlGaAs/GaAs (50 nm/50 nm) is additionally interposed under the Si dope n-type GaAs buffer layer 31.

The epitaxial configuration of the light emitting diode array in the first preferred embodiment will be described below in more detail.

(1) Substrate

In the light emitting diode array according to the preferred embodiments of the present invention, a semi-insulating GaAs substrate 30 made by the LEC method is used as a substrate, instead of the n-type GaAs substrate 10 made by the VGF method in the example.

(2) Light Emitting Part

A Si-doped n-type GaAs buffer layer 31 is interposed between the semi-insulating GaAs substrate 30 made by the LEC method and the p-type GaAs conductive layer 11. Kind of respective compound semiconductor layered on the p-type GaAs conductive layer 11 and a thickness of a respective crystalline layer are selected appropriately in accordance with desired emission wavelength and emission power, and a driving voltage. As a compound semiconductor, GaAs/AlGaAs is used. It is preferable that the light emitting part 1 has a double heterostructure comprising a n-type cladding layer, an active layer, and a p-type cladding layer, and that the light emitting part 1 is formed by separating an epitaxial layer grown on a p-type GaAs conductive layer 11 by a first mesa etching groove 19. Further, a depth of the second mesa etching groove 20 is determined to be a depth which can separate the p-type GaAs conductive layer 11, and can reach a middle of the Si-doped n-type GaAs buffer layer 31, so as to provide the isolation between respective blocks.

In the first preferred embodiment shown in FIG. 6, a light emitting part 1 of the light emitting diode comprises a semi-insulating GaAs substrate 30 made by the LEC method, a p-type AlGaAs etching stopper layer 12, a p-type AlGaAs cladding layer 13, a p-type AlGaAs active layer 14, a n-type AlGaAs cladding layer 15, and a n-type GaAs cap layer 16 sequentially grown on a Si-doped n-type GaAs buffer layer 31 and a p-type GaAs conductive layer 11 grown on the semi-insulating GaAs substrate 30. The n-type GaAs cap layer 16 is removed by etching in a region for a light extracting part (light emitting surface) 9.

In the light emitting part 1, a region directly concerning the light emission has a so-called double heterostructure, in which the p-type AlGaAs active layer 14 having an energy bandgap corresponding to the emission wavelength is sandwiched between the p-type AlGaAs cladding layer 13 and the n-type AlGaAs cladding layer 15, each having an energy bandgap greater than that of the p-type AlGaAs active layer 14.

(3) Mesa Etching Groove

A first mesa etching groove 19 which reaches to the p-type GaAs conductive layer 11 is provided for the purpose of electrically isolating the light emitting part 1 and a bonding part 8. A second mesa etching groove 20 removing the p-type GaAs conductive layer 11 is provided for the purpose of separating respective blocks of the light emitting part 1.

It is preferable that the first mesa etching groove 19 is provided for isolating and separating a bonding part 8 into respective independent parts as well as the light emitting part 1. By forming the independent and respective bonding parts 8, the short-circuit will not be occurred between the respective bonding parts 8, even if Au interconnection is remained on a slant face of the first mesa etching groove 19 at the time of Au interconnection processing. Further, since the bonding part 8 is a remaining portion of the first mesa etching groove 19, an etching area surface will not be increased. According to this structure, a loading effect can be avoided, and it becomes easy to control dimensions of the light emitting part 1, which is a remaining portion of the first mesa etching groove 19 similarly to the bonding part 8.

In addition, the number of the light emitting diodes divided by the second mesa etching groove 20 in one block is equal to the number of common interconnections 4.

(4) Electrode and Interconnection Layer

For each electrode, bonding characteristics and ohmic bonding characteristics with an underlying layer are required. For instance, a laminated electrode such as AuZn/Ni/Au or Ti/Pt/Au is used for the anode electrode 3, and a laminated electrode such as AuGe/Ni/Au is used for the cathode electrode 2.

For the common interconnection 4 as well as a wiring lead out from the cathode electrode 2, anode electrode 3, and common interconnection 4, the good bonding characteristics and high adhesiveness with overlying and underlying layers are required. Therefore, it is preferable that the interconnections and wirings are composed of a plurality of metal layers. Further, it is preferable that a top layer and a bottom layer of the interconnections and wirings is composed of a metal layer having a good bonding characteristics such as Ti, Mo, TiW. For instance, a laminated electrode such as Ti/Au/Ti, Mo/Au/Mo, Tiw/Au/Tiw can be employed. In addition, a laminated electrode of Ti/Pt/Au/Ti may be employed, when the anode electrode 3 and the common interconnection 4 are formed simultaneously by the reason of simplification of the process.

Metal layers of each electrode can be formed by resistance heating vacuum deposition, electron beam heating vacuum deposition, sputtering method, etc., and an oxide layer can be formed in various known film forming methods. It is preferable that the heat treatment (alloying) is conducted for the cathode and anode metal layers so as to provide the metal layers with the ohmic characteristics.

The cathode electrode 2 on each light emitting part 1 is connected to the common interconnection 4 by the means of a lead-out wiring 5c for cathode. Further, the cathode electrode 2 is connected to the bonding pad 6c for cathode by the means of a lead-out wiring 5k for common interconnection. On the other hand, the anode electrode 3 is provided in a strip shape for each block in a position near each light emitting part 1. The anode electrode 3 is extended to a bonding part 8a for anode by means of a lead-out wiring 5a for anode, so that a bonding pad 6a for anode is formed.

Each of lead-out wirings 5c, 5a, and 5k is formed on a second insulating film 18, and each of the lead-out wirings 5c, 5a, and 5k is connected electrically by means of a contact hole 7 formed by etching the second insulating film 18.

(Method for Fabricating a Light Emitting Diode Array)

Next, a preferable method of fabricating a light emitting diode array in the present invention will be explained below.

On an upper surface of a semi-insulating GaAs substrate 30 made by the LEC method, a Si-doped n-type GaAs buffer layer 31 (carrier concentration: 1×10¹⁷ to 5×10⁸ cm⁻³, thickness: 1 μm), a p-type GaAs conductive layer 11 (carrier concentration: 4×10¹⁹ cm⁻³, thickness: 1 μm), a p-type AlGaAs etching stopper layer 12 (carrier concentration: 3×10¹⁹ cm⁻³, thickness: 0.1 μm), a p-type AlGaAs cladding layer 13 (carrier concentration: 1×10⁸ cm⁻³, thickness: 1 μm), a p-type AlGaAs active layer 14 (carrier concentration: 1×10¹⁸ cm⁻³, thickness: 1 μm), a n-type AlGaAs cladding layer 15 (carrier concentration: 2×10¹⁸ cm⁻³, thickness: 3 μm), and a n-type GaAs cap layer 16 (carrier concentration: 1×10¹⁸ cm⁻³, thickness: 0.5 μm) are sequentially grown by Metal-organic Vapor Phase Epitaxy method (MOVPE method).

A lower limit for a carrier concentration of the Si-doped n-type GaAs buffer layer 31 is determined as 1×10¹⁷ cm⁻³. According to the value range of “1×10¹⁷ cm⁻³ or more”, a disadvantage due to the diffusion of Zn dopant, in other words, a short-circuit defect can be prevented, in case where Zn used as p-type dopant is diffused into the Si-doped n-type GaAs buffer layer 31 from the n-type GaAs buffer layer 11. Herein, the n-type GaAs buffer layer 11 is an overlying layer of the Si-doped n-type GaAs buffer layer 31. On the other hand, an upper limit for the carrier concentration of the Si-doped n-type GaAs buffer layer 31 is determined as “5×10¹⁸ cm⁻³”, since the doping process can be actually conducted in this value range.

Wet etching is selectively conducted for a formed crystalline layer. At first, the n-type GaAs cap layer 16 is partially removed, so that a part contacting the cathode electrode 2 in the light emitting part 1 and a bonding part 8 are remained. Next, the first mesa etching groove 19 is provided to have a depth such that the p-type AlGaAs etching stopper layer 12 is exposed. The epitaxial layer grown on the p-type GaAs conductive layer 11 is divided into a plurality of light emitting parts 1, and respective bonding parts 8 independent from the light emitting parts 1 are formed. A region of the p-type GaAs conductive layer 11 is divided by providing the second mesa etching groove 20, so that respective blocks are isolated electrically. Herein, if a depth of the second mesa etching groove 20 is determine such that the Si-doped n-type GaAs buffer layer 31 is slightly etched, the p-type GaAs conductive layer 11 will not remain in case where there is an etching error.

Then, after growing a first insulating film 17 by Chemical Vapor Deposition method (CVD method) to cover the entire top surface of the light emitting diode array, a cathode electrode 2 composed of AuGe/Ni/Au, an anode electrode 3 composed of AuZn/Ni/Au, and a common interconnection 4 composed of Ti/Au/Ti are respectively formed by repeating the vapor deposition and liftoff method.

After growing the second insulating film 18, the lead-out wirings 5a, 5c and 5k composed of Ti/Au/Ti are formed by sputtering and ion milling method.

Further, after growing the second insulating film 18 by CVD method, a contact hole 7 is formed by etching at the cathode electrode 2, anode electrode 3 and four strips of the common interconnection 4, respectively. Interconnection layers of Ti/Au/Ti extending to the respective bonding parts 8 are formed by spattering and ion milling method.

The first insulating film 17 and second insulating film 18 on the light extraction part (light emitting surface) 9 and a scribe area 22 are removed by dry-etching using a known mixed gas such as CHF₃/O₂. A third insulating film 23 and a fourth insulating film 24 are deposited for the purpose of preventing the infiltration of moisture, etc.

The first, second and third insulating films 17, 18, and 23 may be composed of SiO₂ or phospho-silicate glass (PSG). On the other hand, the fourth insulating film 24 is a final passivation film, it is preferable to use a dense film such as a nitride film for the fourth insulating film 24. For instance, the fourth insulating film 24 may be composed of SiN. At this time, in case where a refractive index of the fourth insulating film 24 is different from that of the third insulating film 23, it is necessary to set the film thickness of the third and fourth insulating films 23 and 24, such that these insulating films 23 and 24 will not function as a reflective coating depending on the emission light wavelength. It is preferable to set a total film thickness of the insulating films to be lam or less.

Finally, during the bonding process, an aperture is formed by etching at unnecessary regions of the third insulating film 23 and the fourth insulating film 24 on the bonding pad.

In the second preferred embodiment, the epitaxial configuration of the light emitting part of the light emitting diode array shown in FIG. 6 is replaced with an epitaxial configuration shown in FIG. 7.

In other words, on an upper surface of a semi-insulating GaAs substrate 30 made by the LEC method, a Si-doped GaAs/AlGaAs superlattice buffer layer 40 grown by MOVPE method is interposed. The GaAs/AlGaAs superlattice buffer layer 40 comprises three layers 41 to 43 of GaAs(carrier concentration: 1×10¹⁷ to 5×10¹⁸ cm⁻³, thickness: 50 nm)/AlGaAs (carrier concentration: 1×10¹⁷ to 3×10¹⁸ cm⁻³, thickness: 50 nm).

On an upper surface of the GaAs/AlGaAs superlattice buffer layer 40, a Si-doped n-type GaAs buffer layer 31 (carrier concentration: 1×10¹⁷ to 5×10¹⁸ cm⁻³, thickness: 1 μm), a p-type GaAs conductive layer 11 (carrier concentration: 4×10¹⁹ cm⁻³, thickness: 1 μm), a p-type AlGaAs etching stopper layer 12 (carrier concentration: 3×10¹⁹ cm⁻³, thickness: 0.1 μm), a p-type AlGaAs cladding layer 13 (carrier concentration: 1×10¹⁸ cm⁻³, thickness: 1 μm), a p-type AlGaAs active layer 14 (carrier concentration: 1×10¹⁸cm⁻³, thickness: 1 μm), a n-type AlGaAs cladding layer 15 (carrier concentration: 2×10¹⁸ cm⁻³, thickness: 3 μm), and a n-type GaAs cap layer 16 (carrier concentration: 1×10¹⁸ cm⁻³, thickness: 0.5 μm) are sequentially grown by Metal-organic Vapor Phase Epitaxy method (MOVPE method) to provide an epitaxial configuration.

In such an epitaxial configuration, an effect similar to that of the first preferred embodiment shown in FIG. 6 can be obtained. In the second preferred embodiment, a leak current flown from the buffer layer to the substrate can be more securely prevented by interposing the GaAs/AlGaAs superlattice buffer layer 40 having different bandgaps.

Herein, for the thickness of each of the GaAs/AlGaAs layer 41 to 43, it is preferable that a thickness of GaAs is around 30 to 100 nm and a thickness of AlGaAs is around 30 to 100 nm. It is sufficient if at least one layer is provided as the GaAs/AlGaAs layers 41 to 43.

Although the invention has been described with respect to specific embodiment for complete and clear disclosure, the appended claims are not to be thus limited but are to be construed as embodying all modification and alternative constructions that may be occurred to one skilled in the art which fairly fall within the basic teaching herein set forth.

What is claimed is:

1. A light emitting diode, comprising:
a semi-insulating GaAs substrate;
a GaAs system conductive layer doped with p-dopants which is provided on the semi-insulating GaAs substrate;
a GaAs system light emitting portion provided on the GaAs system conductive layer;
a n-electrode provided on the GaAs system light emitting portion;
a p-electrode provided on a side of the GaAs system light emitting portion and on the semi-insulating GaAs substrate, the p-electrode being connected to the GaAs system conductive layer; and
a GaAs system layer provided between the semi-insulating GaAs substrate and the GaAs system conductive layer, the GaAs system layer preventing the p-dopants from diffusing into the semi-insulating GaAs substrate.

2. The light emitting diode, according to claim 1, wherein:
the GaAs system layer is a n-GaAs buffer layer doped with Si.

3. The light emitting diode, according to claim 1, wherein:
the GaAs system layer is a superlattice layer including AlGaAs and GaAs layers doped with Si.

4. A light emitting diode array, comprising:
a plurality of light emitting diodes being isolated and separated comprising:
a semi-insulating GaAs substrate;
a p-type GaAs conductive layer provided on the semi-insulating GaAs substrate; and
compound semiconductor layers epitaxially grown on the p-type GaAs conductive layer to provide the plurality of light emitting diodes;
wherein:
a Si-doped n-type GaAs buffer layer is interposed between the semi-insulating GaAs substrate and the p-type GaAs conductive layer.

5. The light emitting diode array, according to claim 4, wherein:
a Si-doped GaAs/AlGaAs superlattice buffer layer is interposed under the Si-doped n-type GaAs buffer layer provide between the semi-insulating GaAs substrate and the p-type GaAs conductive layer.

6. The light emitting diode array, according to claim 4, further comprising:
a mesa etching groove for defining the plurality of light emitting diodes, which has an enough depth to divide the p-type GaAs conductive layer and to reach the Si-doped n-type GaAs buffer layer.

7. The light emitting diode array, according to claim 5, further comprising:
a mesa etching groove for defining the plurality of light emitting parts, having an enough depth to divide the p-type GaAs conductive layer and to reach the Si-doped n-type GaAs buffer layer.

8. The light emitting diode array, according to claim 4, wherein:
each of the light emitting parts comprises:
a p-type AlGaAs etching stopper layer, a p-type AlGaAs cladding layer, a p-type AlGaAs active layer, a n-type AlGaAs cladding layer, and a n-type GaAs cap layer sequentially grown on the p-type GaAs conductive layer provided on the semi-insulating GaAs substrate.

9. The light emitting diode array, according to claim 5, wherein:
each of the light emitting parts comprises:
a p-type AlGaAs etching stopper layer, a p-type AlGaAs cladding layer, a p-type AlGaAs active layer, a n-type AlGaAs cladding layer, and a n-type GaAs cap layer sequentially grown on the p-type GaAs conductive layer provided on the semi-insulating GaAs substrate.

10. The light emitting diode array, according to claim 6, wherein:
each of the light emitting parts comprises:
a p-type AlGaAs etching stopper layer, a p-type AlGaAs cladding layer, a p-type AlGaAs active layer, a n-type AlGaAs cladding layer, and a n-type GaAs cap layer sequentially grown on the p-type GaAs conductive layer provided on the semi-insulating GaAs substrate.

11. The light emitting diode array, according to claim 7, wherein:
each of the light emitting parts comprises:
a p-type AlGaAs etching stopper layer, a p-type AlGaAs cladding layer, a p-type AlGaAs active layer, a n-type AlGaAs cladding layer, and a n-type GaAs cap layer sequentially grown on the p-type GaAs conductive layer provided on the semi-insulating GaAs substrate.
